(19) United States
(12) Patent Application Publication
(10) Pub. No.: US 2025/0299724 A1
(43) Pub. Date: Sep. 25, 2025

(54) LOW-VOLTAGE COLUMN SELECT DRIVER FOR HIGH-DENSITY MEMORY DEVICE

(71) Applicant: Micron Technology, Inc., Boise, ID (US)

(72) Inventor: Venkataramana GANGASANI, Meridian, ID (US)

(21) Appl. No.: 19/056,856

(22) Filed: Feb. 19, 2025

Related U.S. Application Data
(60) Provisional application No. 63/567,118, filed on Mar. 19, 2024.

(51) Int. Cl. G11C 11/408; G11C 11/4093

(52) U.S. Cl. CPC G11C 11/4087; G11C 11/4093

(57) ABSTRACT

A memory device includes a column decoder configured to decode a column address. The column decoder includes a column select driver configured to modulate a column select signal based on the column address in order to activate or deactivate a plurality of column selection circuits coupled to a column select line. The column select signal includes an activation pulse for activating the plurality of column selection circuits during an activation interval. The activation pulse includes a first portion having a positive boost signal level and a second portion having an activation signal level that is less than the positive boost signal level. The column select driver is configured to generate the first portion of the activation pulse for a first duration of the activation interval, and, following the first duration, generate the second portion of the activation pulse for a second duration of the activation interval.

### CROSS-REFERENCE TO RELATED APPLICATION

This Patent application claims priority to U.S. Provisional Patent Application No. 63/567,118, filed on Mar. 19, 2024, entitled “LOW-VOLTAGE COLUMN SELECT DRIVER FOR HIGH-DENSITY MEMORY DEVICE,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to a low-voltage column select driver for a high-density memory device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagrammatic view of an example memory device.

FIG. 2 shows a diagram of a memory circuit.

FIG. 3 shows a schematic diagram of a column select (CS) driver according to one or more implementations.

FIG. 4 shows a timing diagram associated with generating a column select signal according to one or more implementations.

FIG. 5 shows a voltage generator according to one or more implementations.

FIG. 6 shows a pulse duration regulator according to one or more implementations.

FIG. 7 shows a driver circuit according to one or more implementations.

FIG. 8 shows a CS driver according to one or more implementations.

FIG. 9A shows a driver circuit according to one or more implementations.

FIG. 9B shows a signal diagram according to one or more implementations.

FIG. 10 is a flowchart of an example method associated with a low-voltage column select driver for a memory device.

### DETAILED DESCRIPTION

A transistor can be referred to as a logic switch or a transistor switch that may be used to complete a circuit connection. The transistor includes a first terminal (e.g., a source or an emitter) and a second terminal (e.g., a drain or a collector). Additionally, a conductive path of the transistor may be controlled by a control electrode, sometimes referred to as a gate, connected to a control terminal of the transistor. A conductive path of the transistor is a gate-controlled conductive channel whose conductivity may be controlled by a control voltage applied to the control electrode of the transistor. For example, the transistor can be turned on or off by activating and deactivating its control electrode. For example, applying a positive voltage across a gate and a source of a metal-oxide-semiconductor field-effect transistor (MOSFET) will keep the MOSFET in its “on” state, while applying a voltage of approximately zero or slightly negative across the gate and the source of the MOSFET will cause the MOSFET to turn “off.”

There is a turn-on process and a turn-off process for switching a transistor on and off. During the turn-on process of an n-channel transistor, a gate driver may be used to provide (source) a gate current (e.g., an ON current) to a gate of the n-channel transistor in order to charge a gate voltage to a sufficient voltage to turn on the n-channel transistor. In contrast, during the turn-off process of the n-channel transistor, the gate driver is used to draw (sink) a gate current (e.g., an OFF current) from the gate of the n-channel transistor in order to discharge the gate voltage sufficiently to turn off the n-channel transistor. A voltage pulse may be output from the gate driver as a control signal. Thus, the control signal may be switched between an ON voltage level and an OFF voltage level for controlling the n-channel transistor. This in turn charges and discharges gate capacitance to correspondingly modulate the gate voltage to turn on and off the n-channel transistor, respectively.

The opposite is true for a p-channel transistor. The gate driver may be used to draw (sink) a gate current (e.g., an ON current) from a gate of the p-channel transistor in order to discharge the gate voltage to a sufficient voltage to turn on the p-channel transistor. In contrast, during the turn-off process of the p-channel transistor, the gate driver is used to provide (source) a gate current (e.g., an OFF current) to the gate of the p-channel transistor in order to charge the gate voltage of the p-channel transistor sufficiently to turn off the p-channel transistor. A control signal applied to the gate of the p-channel transistor may be switched between an ON voltage level and an OFF voltage level for controlling the p-channel transistor. This in turn charges and discharges the gate voltage to turn on and off the p-channel transistor, respectively.

For both n-channel and p-channel transistors, the n-channel and p-channel transistors are off when the gate-source voltage Vgs is approximately a zero value or below a threshold voltage, and the n-channel and p-channel transistors are on when the gate-source voltage Vgs is equal to or greater than the threshold voltage. For this reason, the gate-source voltage Vgs may be referred to as a control voltage.

A memory device may include a column decoder configured to drive column select (CS) signals. Column select circuitry may be configured to implement data movement operations with respect to memory cells located in particular columns of a subarray, complementary digit lines associated with the particular columns, and a shared input/output (I/O) line, as directed by a controller.

As DRAM density increases, a bank height of a memory bank increases. A column select signal may be transmitted into a near edge of the memory bank towards a far edge of the memory bank in order to activate or deactivate a plurality of column selection circuits coupled along a column select line (CSL). The column selection circuits may include transistors that turn on and off based on a charging and discharging of a gate capacitance, respectively. As a result of increased bank height, a column select driver may not be able to drive a column select signal from one rail potential to another rail potential (e.g., rail-to-rail) at a far edge of the memory bank. Additionally, charging and discharging times of a gate capacitance at the far edge of the memory bank may be slower than charging and discharging times of a gate capacitance at the near edge of the memory bank. As a result of a signal propagation distance to the far edge of the memory bank, losses that increase with signal propagation distance, and increased signal propagation times, a signal level (e.g., a voltage level) of the column select signal at the far edge of the memory bank may not be at a level sufficient to appropriately activate or deactivate one or more column selection circuits located at the far edge of the memory bank. Thus, data may not be appropriately written to or read from one or more memory cells located at the far edge of the memory bank during a column select operation.

Some implementations provide a column decoder configured to drive column select signals with all input levels maintained at a low-voltage (LV) level and with a multiple-step voltage level at an output of a CS driver for better rise times and fall times at each column selection circuit of a column select line. For example, the column decoder may drive each column select signal with two or more voltage steps during activation of the column selection circuits, and/or may drive each column select signal with two or more voltage steps during deactivation of the column selection circuits. The column select signal may be generated with boost voltage levels to shorten rise times and fall times during activation and deactivation, respectively. Thus, the column selection circuits located at a far edge of a memory bank may reach turn-on and turn-off voltage levels more quickly such that data may be appropriately written to or read from one or more memory cells located at the far edge of the memory bank during a column select operation.

Some implementations provide a column decoder with a latch style CS driver architecture for LV column address (CA) signals.

Some implementations provide a column decoder with an LV architecture that does not require level shifters to be added to a CS pre-decoder.

Some implementations provide a column decoder with a simple pass gate with single controlled bias voltage that can be utilized for a near edge section CS signal and can be maintained at a uniform CS pulse width in both near and far edges of sections of the memory bank.

Some implementations provide a column decoder with a reduced area when compared with a column decoder having a CS repeater style architecture.

Some implementations provide a column decoder with a single-sided CS driver that generates a rail-to-rail CS pulse across all sections of a DRAM bank, without using a two-sided CS driver or a CS repeater with additional edge sections in a center of the DRAM bank. A single-sided CS driver may be a single driver located at the near edge of the memory bank. In contrast, a two-sided CS driver may include one driver located at the near edge of the memory bank and another driver located at the far edge of the memory bank. A CS repeater may include additional repeater components arranged along the CSL. Both the two-sided CS driver and the CS repeater require more chip area and higher manufacturing costs when compared with a single-sided CS driver that has no CS repeaters.

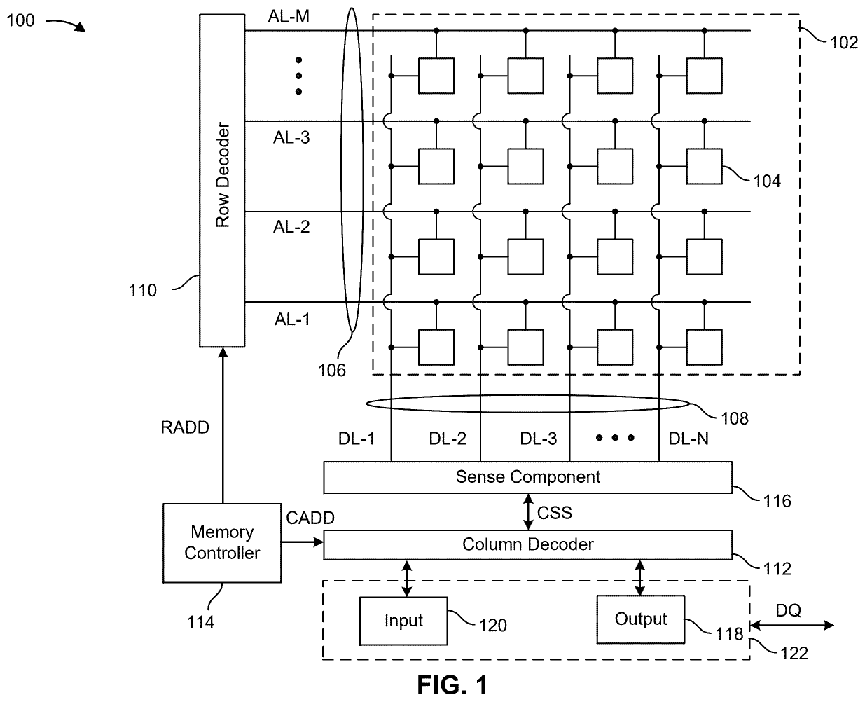

FIG. 1 is a diagrammatic view of an example memory device 100. The memory device 100 may include a memory array 102 that includes multiple memory cells 104. The memory array 102 may form a bank or may be part of a bank. In some implementations, the memory device 100 may include a plurality of banks, each formed by a respective memory array 102. A memory cell 104 is programmable or configurable into a data state of multiple data states (e.g., two or more data states). For example, a memory cell 104 may be set to a particular data state at a particular time, and the memory cell 104 may be set to another data state at another time. A data state may correspond to a value stored by the memory cell 104. The value may be a binary value, such as a binary 0 or a binary 1, or may be a fractional value, such as 0.5, 1.5, or the like. A memory cell 104 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 104 by activating or selecting the appropriate access line 106 (shown as access lines AL-1 through AL-M) and digit line 108 (shown as digit lines DL-1 through DL-N). An access line 106 may also be referred to as a “row line” or a “word line,” and a digit line 108 may also be referred to a “column line” or a “bit line.” Activating or selecting an access line 106 or a digit line 108 may include applying a voltage to the respective line. An access line 106 and/or a digit line 108 may comprise, consist of, or consist essentially of a conductive material, such as a metal (e.g., copper, aluminum, gold, titanium, or tungsten) and/or a metal alloy, among other examples. In FIG. 1, each row of memory cells 104 is connected to a single access line 106, and each column of memory cells 104 is connected to a single digit line 108. By activating one access line 106 and one digit line 108 (e.g., applying a voltage to the access line 106 and digit line 108), a single memory cell 104 may be accessed at (e.g., is accessible via) the intersection of the access line 106 and the digit line 108. The intersection of the access line 106 and the digit line 108 may be called an “address” of a memory cell 104.

In some implementations, the logic storing device of a memory cell 104, such as a cell capacitor, may be electrically isolated from a corresponding digit line 108 by a selection component, such as a cell transistor. The access line 106 may be connected to and may control the selection component. For example, the selection component may be a cell transistor, and the access line 106 may be connected to the gate of the cell transistor. Activating the access line 106 results in an electrical connection or closed circuit between the capacitor of a memory cell 104 and a corresponding digit line 108. The digit line 108 may then be accessed (e.g., is accessible) to either read from or write to the memory cell 104. In some implementations, the memory cells 104 may be DRAM memory cells.

A row decoder 110 and a column decoder 112 may control access to memory cells 104. Thus, the row decoder 110 and the column decoder 112 may each include control logic for generating control signals based on a received row address or a received column address, respectively. For example, the row decoder 110 may receive a row address RADD from a memory controller 114 and may activate the appropriate access line 106 based on the received row address RADD. For example, the row decoder 110 may enable one or more access lines 106 (e.g., word lines) based on a result obtained by decoding the row address RADD. The memory controller 114 may be part of a host device. The host device may be an external processor, such as a microprocessor. Similarly, the column decoder 112 may receive a column address CADD from the memory controller 114 and may activate the appropriate digit line 108 based on the column address CADD. The column decoder 112 may activate one or more column selection circuits via one or more column select lines (CSLs). Thus, the column decoder 112 may include a plurality of column select (CS) drivers, with each CS driver configured to drive a respective CSL. The column decoder 112 may be arranged at one side of the memory array 102 (e.g., on one side of the bank). The column decoder 112 may decode the column address CADD and may output a column select signal CSS to the memory array 102 according to the decoding result.

Upon accessing a memory cell 104, the memory cell 104 may be read (e.g., sensed) by a sense component 116 to determine the stored data state of the memory cell 104. For example, after accessing the memory cell 104, the capacitor of the memory cell 104 may discharge onto its corresponding digit line 108. Discharging the capacitor may be based on biasing, or applying a voltage, to the capacitor. The discharging may induce a change in the voltage of the digit line 108, which the sense component 116 may compare to a reference voltage (not shown) to determine the stored data state of the memory cell 104. For example, if the digit line 108 has a higher voltage than the reference voltage, then the sense component 116 may determine that the stored data state of the memory cell 104 corresponds to a first value, such as a binary 1. Conversely, if the digit line 108 has a lower voltage than the reference voltage, then the sense component 116 may determine that the stored data state of the memory cell 104 corresponds to a second value, such as a binary 0. The detected data state of the memory cell 104 may then be output (e.g., via the column decoder 112) to an output component 118 (e.g., a data buffer). A memory cell 104 may be written (e.g., set) by activating the appropriate access line 106 and digit line 108. The column decoder 112 may receive data, such as input from input component 120, to be written to one or more memory cells 104. A memory cell 104 may be written by applying a voltage across the capacitor of the memory cell 104.

The output component 118 and the input component 120 may form a data input/output (I/O) circuit 122 that may output data DQ from the memory array 102 to the external processor during a read operation or may input data DQ from the external processor to the memory array 102 during a write operation. The data I/O circuit 122 may be arranged adjacent to the column decoder 112 for quick access to the column decoder 112.

The memory controller 114 may control the operation (e.g., read, write, re-write, refresh, and/or recovery) of the memory cells 104 via the row decoder 110, the column decoder 112, and/or the sense component 116. The memory controller 114 may generate row address signals and column address signals to activate the desired access line 106 and digit line 108. The memory controller 114 may also generate and control various voltages used during the operation of the memory array 102.

As indicated above, FIG. 1 is provided as an example. Other examples may differ from what is described with respect to FIG. 1.

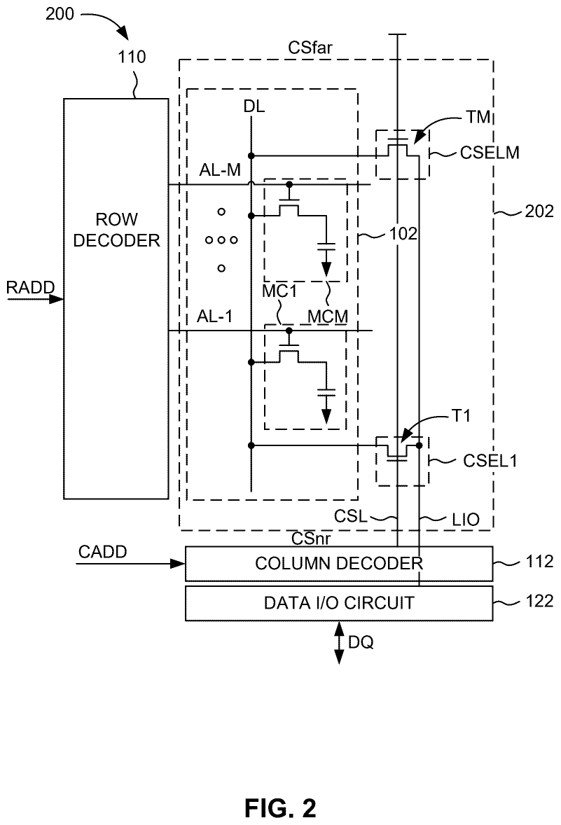

FIG. 2 shows a diagram of a memory circuit 200. The memory circuit 200 may be implemented in the memory device 100 described in connection with FIG. 1. The memory circuit 200 may include a bank 202 that includes the memory array 102 and a plurality of column selection circuits CSEL1 and CSELM.

The memory array 102 may include a plurality of access lines AL and a plurality of data lines DL. FIG. 2 illustrates two access lines AL1 and ALM and one data line DL, for convenience of description. The access line AL1 may be positioned at a lower region of the memory array 102, or at a near side CSnr of the column select line CSL, and the access line ALM may be positioned at an upper region of the memory array 102, or at the far side CSfar of the column select line CSL. The column select line CSL may extend from the column decoder 112 (e.g., from a column select driver) arranged proximate to a near side of the bank 202 to a far side of the bank 202.

The memory array 102 may include a plurality of memory cells MC1 and MCM arranged at the respective intersections between the plurality of access lines AL1 and ALM and the plurality of data lines DL. The memory cell MC1 may be coupled to the access line AL1 and the data line DL, and the memory cell MCM may be coupled to the access line ALM and the data line DL. The memory cell MC1 may include a first cell transistor and a first cell capacitor. The memory cell MCM may include a second cell transistor and a second cell capacitor. Thus, each memory cell 104 may include a cell transistor (or another type of selection circuit) and a cell capacitor.

A memory cell 104 may be accessed (e.g., written to, read from, and/or erased) using signals on a combination of lines that are coupled to the memory cell 104, the combination of lines being shown as a respective access line and a respective digit line. The cell transistor (sometimes called an access transistor) may include a gate coupled to a respective access line. The cell capacitor includes two electrodes separated by an insulator. In some implementations, the capacitor is a ferroelectric capacitor, and the insulator is a ferroelectric insulator that comprises, consists of, or consists essentially of ferroelectric material. Alternatively, the capacitor may be a linear dielectric capacitor, and the insulator may be a linear dielectric insulator that comprises, consists of, or consists essentially of linear dielectric material. Alternatively, the cell capacitor may be a paraelectric capacitor, and the insulator may be a paraelectric insulator that comprises, consists of, or consists essentially of paraelectric material. When the access line is activated (e.g., when a voltage is applied to the access line), the gate of the cell transistor coupled to the access line may be activated. When the gate of the cell transistor is activated, the cell transistor couples the digit line to the cell capacitor. A state of the memory cell 104 may then be written to or read from via the digit line.

To write to (or program) a memory cell 104, the respective access line may be activated, and a voltage may be applied across the cell capacitor by controlling the voltage applied to the cell capacitor via the respective digit line.

In some implementations, data may be stored using the cell capacitor by controlling a voltage difference and/or a polarity difference of the cell capacitor (e.g., of the insulator between the two electrodes). For a linear dielectric capacitor or a paraelectric capacitor, the electrode insulated from the cell transistor may be grounded, and the cell capacitor may be charged by applying a voltage to the electrode coupled to the cell transistor via the digit line.

To read a memory cell 104 (e.g., a state stored by the cell capacitor), the access line may be activated, and a voltage may be sensed from the data line. The magnitude of the change in stored charge may depend on the stored state of the cell capacitor (e.g., whether the stored state is a logic “1” state or a logic “0” state). This may or may not induce a threshold change in the voltage of the digit line based on the charge stored on the cell capacitor. The change in voltage or lack of change in voltage of the digit line (or a magnitude of the change in voltage) may be used to determine the stored state of the cell capacitor. For example, if the change in voltage satisfies a threshold, then the read operation indicates that a first state was stored in the cell capacitor, whereas if the change in voltage does not satisfy the threshold, then the read operation determines that a second state was stored in the cell capacitor. In some cases, multiple threshold voltages may be used, such as when the capacitor is capable of storing more than two data states (e.g., for a multi-level cell, a triple-level cell, and so on).

The column selection circuits CSEL1 and CSELM may correspond to the memory cells MC1 and MCM, respectively. Additional column selection circuits may be provided, depending on a height of the bank 202. For example, additional column selection circuits may be provided between column selection circuits CSEL1 and CSELM. In other words, a number of column selection circuits may depend on a length of the column select line CSL. Thus, the column select line CSL may have a length corresponding to the height of the bank 202. In some implementations, a column selection circuit may be provided for each memory cell.

The column selection circuit CSEL1 may transfer data of the data line DL to a data I/O line LIO in response to the column select signal CSS. The data may correspond to data stored in the memory cell MC1. The column selection circuit CSEL1 may include a selection transistor T1. The selection transistor T1 may be coupled between the data line DL and the data I/O line LIO, and may receive the column select signal CSS at a gate terminal.

The column selection circuit CSELM may transfer the data of the bit line DL to the data I/O line LIO in response to the column select signal CSS. The data may correspond to data stored in the memory cell MCM. The column selection circuit CSELM may include a selection transistor TM. The selection transistor TM may be coupled between the data line DL and the data I/O line LIO, and may receive the column select signal CSS through a gate terminal. The column select signal CSS may be applied through the column select line CSL. Thus, the column select line CSL may be coupled to the gate terminal of each selection transistor that is coupled to the data line DL. In some implementations, when a plurality of data lines DL are provided, the column select line CSL may be coupled to each of the data lines DL via corresponding column selection circuits.

The column selection circuits CSEL1 and CSEL2 may be operated simultaneously according to the column select signal CSS transmitted on the column select line CSL. In other words, the column select signal CSS may be used to activate both column selection circuits CSEL1 and CSEL2 or deactivate both column selection circuits CSEL1 and CSEL2. Thus, a plurality of column selection circuits may be arranged along a length of the column select line CSL, and the plurality of column selection circuits may be configured to connect or disconnect the data I/O line LIO and the data line DL according to the column select signal CSS. For example, when the column selection circuits CSEL1 and CSEL2 are operated by the column select signal CSS, data of the memory cell MC1 and of the memory cell MCM may be transferred to the data I/O line LIO through the data line DL. The data DQ transferred to the data I/O line LIO may be output through the data I/O circuit 122.

When the data line DL is selected by the column decoder 112 for a read operation, the selection transistors T1 and TM may be turned on, according to the column select signal CSS, to transmit the voltage of the data line DL to the data I/O line LIO. The data I/O circuit 122 may output the data DQ applied from the data I/O line LIO to the external processor. Thus, a CS driver of the column decoder 112 may be a gate driver for activating and deactivating the column selection circuits CSEL1 and CSEL2 by turning on or off the selection transistors T1 and TM, respectively.

When the data line DL is selected by the column decoder 112 for a write operation, the selection transistors T1 and TM may be turned on, according to the column select signal CSS, to transmit the voltage of the data I/O line LIO to the data line DL. At this time, any cell transistor that is turned on may enable its respective cell capacitor to charge or discharge based on the voltage of the data I/O line LIO.

As indicated above, FIG. 2 is provided as an example. Other examples may differ from what is described with respect to FIG. 2.

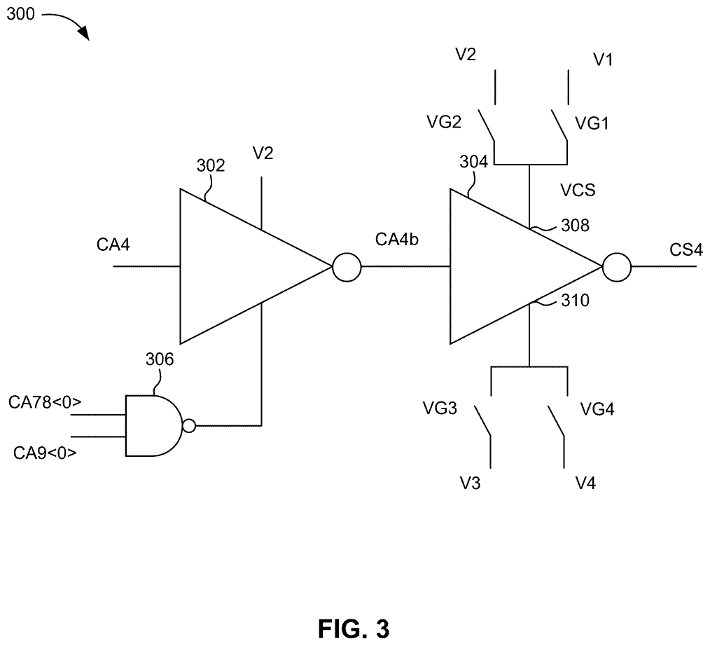

FIG. 3 shows a schematic diagram of a CS driver 300 according to one or more implementations. The CS driver 300 may include a first inverter 302 and a second inverter 304 coupled in series. The first inverter 302 may be configured to receive a control signal CA4 corresponding to the column address CADD. For example, the column decoder 112 (not illustrated in FIG. 3) may decode the column address CADD and generate or otherwise derive one or more control signals (e.g., control signals CA456, CA78, and CA9) based on a decoding of the column address CADD. Control signal CA4 may be correspond to a portion of control signal CA456, such as a particular bit of the control signal CA456.

The CS driver 300 may also include a NAND gate 306 that is coupled to a negative power supply terminal of the first inverter 302. The NAND gate 306 may be configured to enable the first inverter 302 when both inputs to the NAND gate 306 are at a logic 1 value. When both inputs to the NAND gate 306 are at a logic 1 value, an output of the NAND gate 306 is a logic 0 value and the negative power supply terminal of the first inverter 302 is appropriately grounded at a ground potential. When both inputs to the NAND gate 306 are not at a logic 1 value output of the NAND gate 306, the output of the NAND gate 306 is a logic 1 value and the negative power supply terminal of the first inverter 302 is not appropriately grounded. Thus, control signals CA78 and CA9 may be used as inputs to the NAND gate 306 to enable or disable the first inverter 302, and thus enable or disable the CS driver 300. The first inverter 302 may generate a first inverted signal CA4b based on the control signal CA4.

The second inverter 304 has a first power supply terminal 308 (e.g., a positive power supply terminal) and a second power supply terminal 310 (e.g., a negative power supply terminal). The second inverter 304 may be coupled to an output of the first inverter 302 and configured to generate a column select signal CS4 (e.g., a second inverted signal) corresponding to the control signal CA4 based on a first supply potential (e.g., V1 or V2) coupled to the first power supply terminal 308 and a second supply potential (e.g., V3 or V4) coupled to the second power supply terminal 310. For example, the first supply potential defines a logic 1 value of an output voltage of the second inverter 304, and the second supply potential defines a logic 0 value of the output voltage of the second inverter 304. For example, the logic 1 value of the output voltage of the second inverter 304 will be V1 when V1 is connected to the first power supply terminal 308, and will be V2 when V2 is connected to the first power supply terminal 308. The logic 0 value of the output voltage of the second inverter 304 will be V3 when V3 is connected to the second power supply terminal 310, and will be V4 when V4 is connected to the second power supply terminal 310.

In the examples described herein, V1 may correspond to an activation signal level, V2 may correspond to positive boost signal level, V3 may correspond to a negative boost signal level, and V4 may correspond to a deactivation signal level. The activation signal level V1 may be less than the positive boost signal level V2. For example, the activation signal level V1 may be 1 V and the positive boost signal level V2 may be 2 V. Additionally, the deactivation signal level V4 that may be greater than the negative boost signal level V3. For example, the deactivation signal level V4 may be 0 V (e.g., ground potential) and the negative boost signal level V3 may be a negative voltage (e.g. −1 V). The activation signal level V1 may be equal to or greater than a threshold voltage of each column selection circuit, and the deactivation signal level v4 may be less than the threshold voltage of each column selection circuit. For example, for implementations in which the plurality of column selection circuits CSEL1 and CSEL2 are transistors, the activation signal level V1 may be equal to or greater than a threshold voltage of each transistor, and the deactivation signal level V4 may be less than the threshold voltage.

The CS driver 300 may include a first switch VG1 coupled between a first voltage source corresponding to the activation signal level V1 and the first power supply terminal 308, a second switch VG2 coupled between a second voltage source corresponding to the positive boost signal level V2 and the first power supply terminal 308, a third switch VG3 coupled between a third voltage source corresponding to the negative boost signal level V3 and the second power supply terminal 310, and a fourth switch VG4 coupled between a fourth voltage source corresponding to the deactivation signal level V4 and the second power supply terminal 310. The column decoder 112 may include control logic for controlling the first switch VG1, the second switch VG2, the third switch VG3, and the fourth switch VG4 based on the column address CADD to generate the column select signal CS4 with an activation pulse and/or a deactivation pulse. For example, the column decoder 112 may control the first switch VG1 and the second switch VG2 based on the column address CA4 to generate the activation pulse. The column decoder 112 may control the third switch VG3 and the fourth switch VG4 based on the column address CA4 to generate the deactivation pulse.

The CS driver 300, and particularly the second inverter 304, may modulate the column select signal CS4 based on the control signal CA4 derived from the column address CADD in order to activate or deactivate the plurality of column selection circuits CSEL1 and CSEL2. The column select signal CA4 may include an activation pulse for activating the plurality of column selection circuits during an activation interval. Moreover, the activation pulse may include a first portion having the positive boost signal level V2 and a second portion having the activation signal level V1 that is less than the positive boost signal level V2. The CS driver 300, and particularly the second inverter 304, may generate the first portion of the activation pulse for a first duration of the activation interval, and may generate the second portion of the activation pulse for a second duration of the activation interval. The second duration of the activation interval may be subsequent to the first duration of the activation interval.

As a result, the activation pulse may initially have a higher voltage level during the first portion of the activation pulse to more quickly charge the gate capacitances of the column selection circuits located at the far edge of the bank with the positive boost signal level V2. Applying the positive boost signal level V2 during the first portion of the activation pulse may improve a rise time of the activation pulse at the far edge of the bank. In other words, the rise time of the gate voltages of the column selection circuits located at the far edge of the bank may be shortened more than would otherwise be possible without the positive boost signal level V2, such that the gate capacitances charge more quickly and the gate voltages are able to reach a threshold voltage in an appropriate timeframe for activating (turning on) all column selection circuits coupled to the column select line CSL. For example, applying the positive boost signal level V2 allows the gate voltage of the column selection circuits to reach the activation signal level V1 more quickly.

The first duration of the positive boost signal level V2 is sufficiently long to enable the gate voltages of the column selection circuits to sufficiently increase for turn on (e.g., the gate capacitances are sufficiently charged for turn on). However, if the activation pulse is maintained at the positive boost signal level V2 for an entire duration of the activation pulse, a fall time for deactivating the column selection circuits may be degraded, and deactivation may not be appropriately achieved. Thus, the activation pulse may be reduced to the activation signal level V1 for the second duration of the activation pulse. The activation signal level V1 is sufficient for maintaining the column selection circuits in an activated state for a remaining portion of an activation period.

Additionally, or alternatively, the CS driver 300 is configured to deactivate the plurality of column selection circuits during a deactivation interval. The column select signal CS4 may have a deactivation pulse for deactivating the plurality of column selection circuits during the deactivation interval. For example, the CS driver 300, and particularly the second inverter 304, may generate the deactivation pulse at the negative boost signal level V3 for a first duration of the deactivation interval and maintain the column select signal CS4 at the deactivation signal level V4 that is greater than the negative boost signal level V3 for a second duration of the deactivation interval. The second duration of the deactivation interval may be subsequent to the first duration of the deactivation interval.

As a result, the deactivation pulse may initially have a lower (negative) voltage level during the first portion of the deactivation pulse to more quickly discharge the gate capacitances of the column selection circuits located at the far edge of the bank with the negative boost signal level V3. Applying the negative boost signal level V3 during the first portion of the deactivation pulse may improve a fall time of the deactivation pulse at the far edge of the bank. In other words, the fall time of the gate voltages of the column selection circuits located at the far edge of the bank may be shortened more than would otherwise be possible without the negative boost signal level V3, such that the gate capacitances discharge more quickly and the gate voltages are able to reach a turnoff threshold voltage in an appropriate timeframe for deactivating (turning off) all column selection circuits coupled to the column select line CSL. For example, applying the negative boost signal level V3 allows the gate voltage of the column selection circuits to reach the deactivation signal level V4 more quickly.

The first duration of the negative boost signal level V3 is sufficiently long to enable the gate voltages of the column selection circuits to sufficiently decrease for turn off (e.g., the gate capacitances are sufficiently discharged for turn off). However, if the deactivation pulse is maintained at the negative boost signal level V3 for an entire duration of the deactivation pulse, the rise time for activating the column selection circuits may be degraded and activation may not be appropriately achieved. Thus, the deactivation pulse may be increased to the deactivation signal level V4 for the second duration of the deactivation pulse. The deactivation signal level V4 is sufficient for maintaining the column selection circuits in a deactivated state for a remaining portion of a deactivation period.

In some implementations, the first duration T1 of the activation interval 401 and the first duration T1′ of the deactivation interval 402 are variable, and can depend on a location of the column select line CSL within the bank.

In some implementations, a first difference between the positive boost signal level V2 and the activation signal level V1 is variable, and can depend on a location of the column select line CSL within the bank.

In some implementations, a second difference between the negative boost signal level V3 and the deactivation signal level V4 is variable, and can depend on a location of the column select line CSL within the bank.

As indicated above, FIG. 3 is provided as an example. Other examples may differ from what is described with respect to FIG. 3.

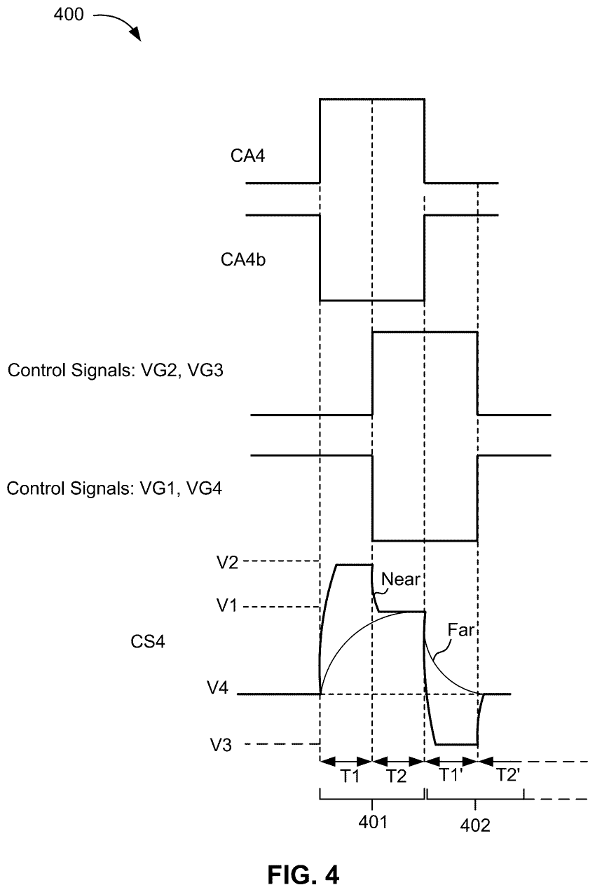

FIG. 4 shows a timing diagram 400 associated with generating a column select signal according to one or more implementations.

The timing diagram 400 shows an activation interval 401, during which all column selection circuits coupled to the column select line CSL are to be activated, and a deactivation interval, during which all column selection circuits coupled to the column select line CSL are to be deactivated. The activation interval 401 includes a first duration T1 and a second duration T2. The positive boost signal level V2 is applied by the column select signal CS4 during the first duration T1 by closing the second switch VG2 and opening the first switch VG1. The activation signal level V1 is applied by the column select signal CS4 during the second duration T2 by closing the first switch VG1 and opening the second switch VG2.

The deactivation interval 402 includes a first duration T1′ and a second duration T2′. The second duration T2′ may be a remaining duration of the deactivation interval 402 until a next activation interval is triggered. The negative boost signal level V3 is applied by the column select signal CS4 during the first duration T1′ by closing the third switch VG3 and opening the fourth switch VG4. The deactivation signal level V4 is applied by the column select signal CS4 during the second duration T2′ by closing the fourth switch VG4 and opening the third switch VG3.

In this example, inverter delays are ignored. The first switch VG1 and the second switch VG2 may be PMOS switches. Thus, the second switch VG2 may turn on when its control signal goes low. Similarly, the first switch VG1 may turn on when its control signal goes low. The third switch VG3 and the fourth switch VG4 may be NMOS switches. Thus, the third switch VG3 may turn on when its control signal goes high. Similarly, the fourth switch VG4 may turn on when its control signal goes high. However, the control scheme may be modified based on doping types of the switches.

The column select signal CS4 has different pulse patterns at the near edge of the bank and at the far edge of the bank. The pulse pattern at the near edge of the bank has a stepped pattern for rising and falling edges. The pulse pattern at the far edge of the bank has a smoother transition for rising and falling edges. The column select signal CS4 is able to reach the activation signal level V1 at the far edge of the bank due to the positive boost signal level V2 being applied for the first duration T1 of the activation interval 401. In addition, the column select signal CS4 is able to reach the deactivation signal level V4 at the far edge of the bank due to the negative boost signal level V3 being applied for the first duration T1′ of the deactivation interval 402.

As indicated above, FIG. 4 is provided as an example. Other examples may differ from what is described with respect to FIG. 4.

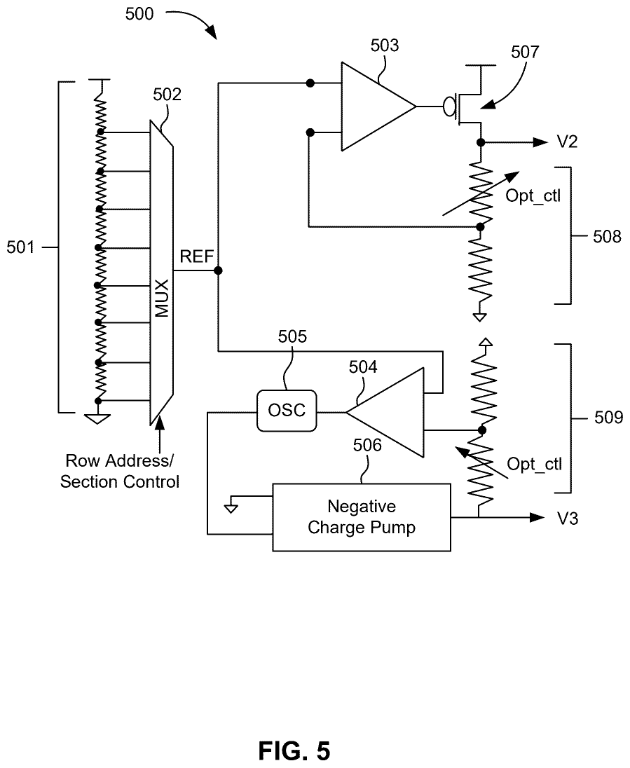

FIG. 5 shows a voltage generator 500 according to one or more implementations. The voltage generator 500 may be configured to generate the positive boost signal level V2 and the negative boost signal level V3 based on a section of the bank controlled by a column select driver. Thus, by the voltage generator 500 being able to vary the positive boost signal level V2, a first difference between the positive boost signal level V2 can be adjusted. Also, by the voltage generator 500 being able to vary the negative boost signal level V3, a second difference between the negative boost signal level V3 and the deactivation signal level V4 can be adjusted.

The voltage generator 500 may include a first voltage divider 501 with multiple taps, and a multiplexer 502 connected to the multiple taps as reference inputs (e.g., reference voltages). In addition, the multiplexer 502 may have control input for receiving a section control signal. The section control signal may be a row address or a section control bit (e.g., a portion of a column address). The multiplexer 502 may select one of the reference inputs for output as a reference voltage REF.

The voltage generator 500 may also include a first differential component 503 and a second differential component 504. The first differential component 503 and the second differential component 504 may be differential comparators, such as differential amplifiers. The voltage generator 500 may also include an oscillator 505, a negative charge pump 506, a transistor 507, a second voltage divider 508 with a first variable resistor, and a third voltage divider 509 with a second variable resistor. The resistive values set for the first variable resistor and the second variable resistor may be configurable based on a row address. The voltage generator 500 may generate the positive boost signal level V2 and the negative boost signal level V3 based on the reference voltage REF selected by the multiplexer 502, based on the section control signal, and based on resistive values set for the first variable resistor and the second variable resistor.

As indicated above, FIG. 5 is provided as an example. Other examples may differ from what is described with respect to FIG. 5.

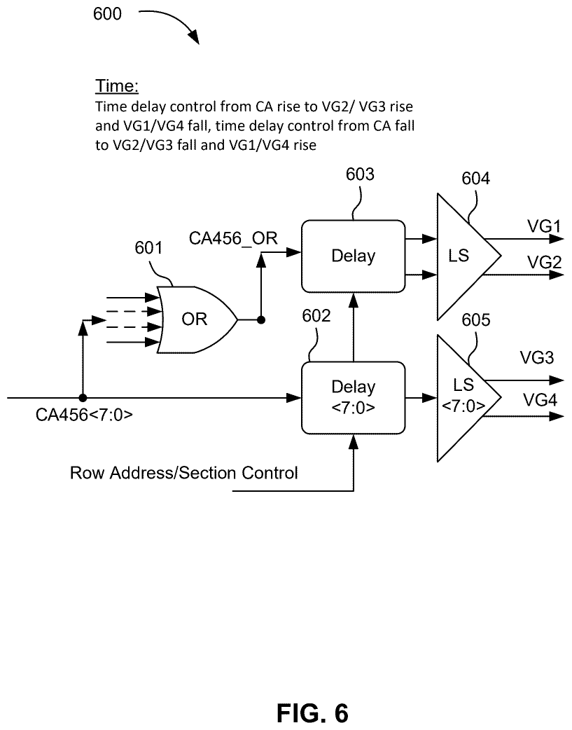

FIG. 6 shows a pulse duration regulator 600 according to one or more implementations. The pulse duration regulator 600 may be configured to regulate the first duration T1 of the activation interval and the first duration T1′ of the deactivation interval based on a section of the bank controlled by a column select driver.

The pulse duration regulator 600 may include an OR gate 601 that receives a control signal CA456, a first delay element 602 that receives the control signal CA456, a second delay element 603, a first level shifter 604, and a second level shifter 605. The first delay element 602 and the second delay element 603 may regulate variable delays based on a section control signal. The section control signal may be a row address or a section control bit (e.g., a portion of a column address). The first level shifter 604 may generate control signals for the first switch VG1 and the second switch VG2. The first duration T1 may be adjusted based on the delay applied by the second delay element 603, according to the section control signal. The second level shifter 605 may generate control signals for the third switch VG3 and the fourth switch VG4. The first duration T1′ may be adjusted based on the delay applied by the first delay element 602, according to the section control signal.

As indicated above, FIG. 6 is provided as an example. Other examples may differ from what is described with respect to FIG. 6.

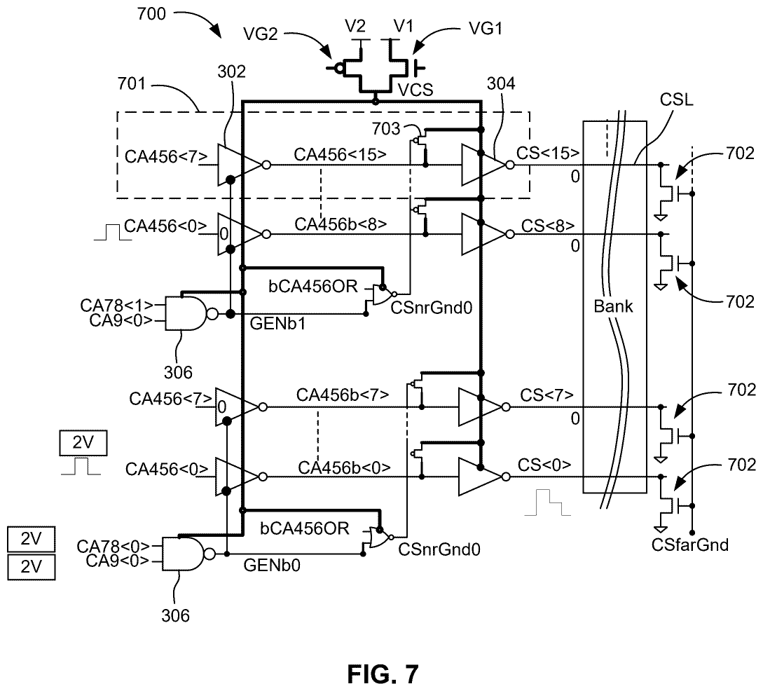

FIG. 7 shows a driver circuit 700 according to one or more implementations. The driver circuit 700 includes a plurality of CS drivers 701 coupled to respective column select lines CSLs. The plurality of CS drivers 701 may be similar to CS driver 300, with the exception that the third switch VG3 and the fourth switch VG4 are not provided for improving a fall time of the column select signal. Instead, the driver circuit 700 may include a column select ground line CSfarGnd having a ground potential and a plurality of pull-down transistors 702 coupled to the column select ground line CSfarGnd. Each pull-down transistor 702 is connected to a far end of a respective column select line CSL. The column decoder 112 may generate a pull-down control signal, and apply the pull-down control signal to the column select ground line CSfarGnd to control an on/off state of the pull-down transistors 702. A pull-down transistor 702 may be activated (turned on) to improve the fall time of a column select signal at the far end of a column select ling CSL without using the third switch VG3 (e.g., without using a negative supply voltage). A pull-down transistor 702 may be activated, for example, during the first duration T1′ of the deactivation interval to improve the fall time of the column select signal at the far end of a column select line CSL. The pull-down transistor 702 may be deactivated (turned off), for example, during the second duration T2′ of the deactivation interval and during an entire duration of the activation interval.

Using the column select ground line CSfarGnd and the plurality of pull-down transistors 702 may improve the reliability of the CS drivers and save chip area that would otherwise be used to accommodate a negative voltage generator, such as a negative charge pump. In addition, pull down control for a plurality of column select lines CSLs may be simplified with a single control signal, CSfarGnd, instead of separately controlling a respective third switch VG3 and a respective fourth switch VG4 for each CS driver. Thus, by controlling a timing of a pull-down control signal applied to the column select ground line CSfarGnd, the fall time for all column select signals can be controlled.

In this example, the column decoder 112 may be configured to toggle control signals CA456, CA78, and CA9 between the positive boost signal level V2 (e.g., 2 V) and a ground potential (e.g., 0 V) based on the column address CADD. As a result, a pre-decoder of the column decoder 112 may include level shifters to drive the control signals CA456, CA78, and CA9 to positive boost signal level V2.

In addition, the first inverter of each CS driver 701 may include a first pair of high-voltage transistors that can handle the activation signal level V2, and the second inverter of each CS driver 701 may include a second pair of high-voltage transistors that can handle the activation signal level V2.

Since the CS drivers 701 are latch type, an LV PMOS transistor 703, which is connected to a corresponding CA456b<0> node, initiates a voltage level to high. This makes the CS<0> node low (e.g., the CCS) low.

GENb0, a NAND gate output of a first NAND gate 306, controls a first set of eight CS drivers. GENb1, a NAND gate output of a second NAND gate 306, controls a second set of eight CS drivers. When GENb0 or GENb1 is high, only one of the CS drivers in that set generates a CS pulse in response to CA control input (CA456<7:0>). bCA456OR is complementary to CA456OR, which goes high when every one among CA456<7:0> goes high. CSnrGnd0 goes low whenever bCA456OR goes high and pulls down the CS signal CSS and improves the fall time of the CS signal CSS.

As indicated above, FIG. 7 is provided as an example. Other examples may differ from what is described with respect to FIG. 7.

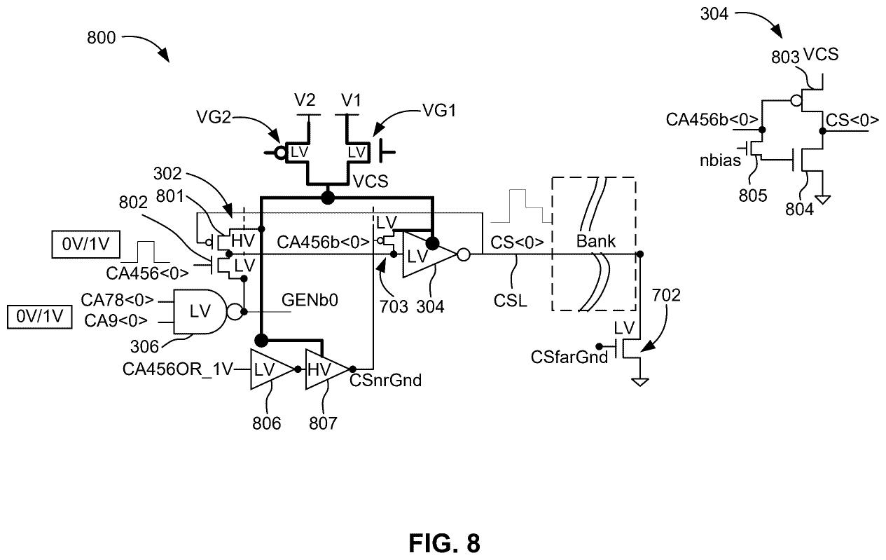

FIG. 8 shows a CS driver 800 according to one or more implementations. The CS driver 800 is configured to drive a column select line in a similar manner as described in connection with FIG. 7. However, the column decoder 112 may be configured to toggle the control signals CA456, CA78, and CA9 between the activation signal level V1 (e.g., 1 V) and a ground potential (e.g., deactivation signal level V4 or 0 V) based on the column address. In other words, the CS drivers may be provided with a 1 V control input instead of a 2 V control input. As a result, level shifters may not be needed to drive the control signals CA456, CA78, and CA9, since the input control does not exceed the activation signal level V1.

The first inverter 302 may include a high-voltage PMOS transistor 801 and a low-voltage NMOS transistor 802. The second inverter 304 may include a pair of low-voltage transistors 803 and 804, as well as an nbias transistor 805. The nbias transistor 805 transistor limits or clamps a voltage received from CA456b<0> and passes that limited voltage from CA456b<0> to a gate of the low-voltage transistor 804. Thus, the nbias transistor 805 may limit the gate voltage of the low-voltage transistor 804 and may protect the low-voltage transistor 804 from reliability issues.

Thus, three of the inverter transistors (e.g., transistors 802, 803, and 804) may be designed as low-voltage transistors due to the control signal CA456 being a low-voltage signal (e.g., a 1 V signal). A control electrode of the high-voltage PMOS transistor 801 may be coupled to an output of the second inverter 304 (e.g., to the column select line CSL). The transistor 801 is a high-voltage transistor due to the column select signal being coupled to the control electrode of the high-voltage PMOS transistor 801 and being driven periodically to the positive boost signal level V2 (e.g., 2 V).

A control signal CA456OR_1V may be provided to a series of inverters 806 and 807 to generate a control signal CSnrGnd. The control signal CA456OR_1V goes high whenever one among CA456<7:0> goes high. CSnrGnd goes low whenever CA456OR_1V goes low and pulls down the CS signal CSS and improves the fall time of CS signal CSS.

The CS driver responds to CA456<0> input only when control signals CA78<0>, CA9<0> both go high. When control signal CA456<0> goes high, the low-voltage NMOS transistor 802, due to being a LV transistor, behaves like a strong NMOS transistor when compared to the high-voltage PMOS transistor 801.

Since the CS driver 800 is a latch type, an LV PMOS transistor 703, which is connected to a CA456b<0> node, initiates a voltage level to high. This makes the CS<0> node low. When control signal CA456<0> starts rising to go high, then initially the strong LV NMOS 802 of first stage inverter 302 pulls down quickly compared to the pull up of the weak HV PMOS transistor 801.

CSfarGnd helps to improve the fall time of a CS pulse by discharging the far side of CS line CSL, and the CSnrGnd helps to improve the fall time of the CS pulse by quickly turning on the NMOS pulldown transistor 804 of the final stage inverter 304 and discharges the near CS line. The first and second switches VG1 and VG2 are used to create a boosted voltage level for the first time period of the CA high pulse.

As indicated above, FIG. 8 is provided as an example. Other examples may differ from what is described with respect to FIG. 8.

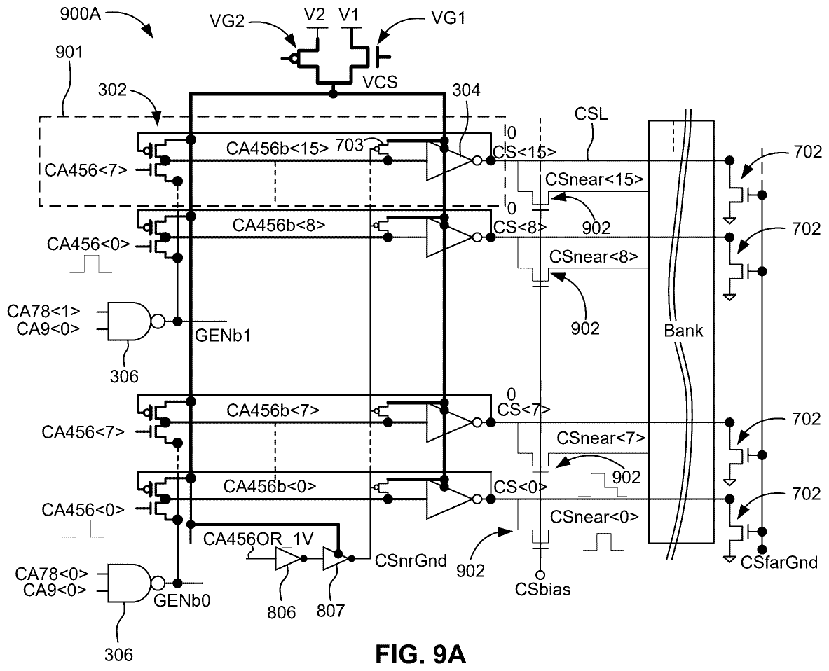

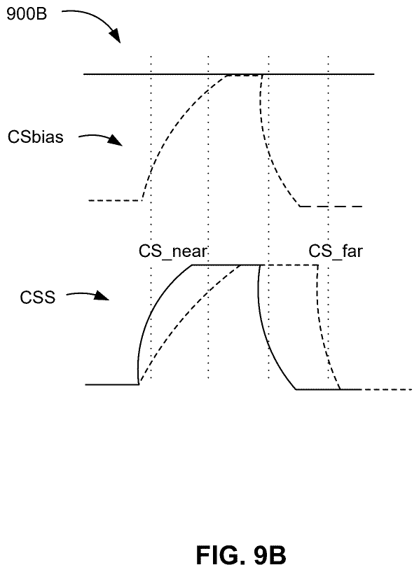

FIG. 9A shows a driver circuit 900A according to one or more implementations. The driver circuit 900A may include the column select ground line CSfarGnd and the plurality of pull-down transistors 702, as similarly described in connection with FIG. 7. In addition, the driver circuit 900A may include a plurality of CS drivers 901 coupled to respective column select lines CSLs. The CS drivers 901 may have a similar configuration to the CS driver 800 described in connection with FIG. 8.

The driver circuit 900A may include a column select bias line CSbias and a plurality of bias transistors 902 connected to the column select bias line CSbias. Each bias transistor 902 is connected to a near end of a respective column select line CSL. The column decoder 112 may generate a bias control signal, and apply the bias control signal to the column select bias line CSbias to control an on/off state of the bias transistors 902. A bias transistor 902 may be activated (turned on) to shape the column select signals so that a pulse shape of a column select signal at the near end of the column select line CSL is similar to a pulse shape of the column select signal at the far end of the column select line CSL. In other words, each bias transistor 902 may be controlled to generate a column select signal that is uniform across the length of the column select line CSL.

As indicated above, FIG. 9A is provided as an example. Other examples may differ from what is described with respect to FIG. 9A.

FIG. 9B shows a signal diagram 900B according to one or more implementations. The signal diagram 900B shows a bias control signal applied to the column select bias line CSbias and a column select signal CSS. The pulse shape of the column select signal CSS at the near end of the column select line CSL is similar to the pulse shape of the column select signal at the far end of the column select line CSL. Thus, controlling the bias transistor 902 enables a uniform CS pulse in both near and far edge sections of the bank. Alternatively, a weak driver may be used for the near edge section to achieve a uniform CS pulse in both near and far edge sections of the bank.

As indicated above, FIG. 9B is provided as an example. Other examples may differ from what is described with respect to FIG. 9B.

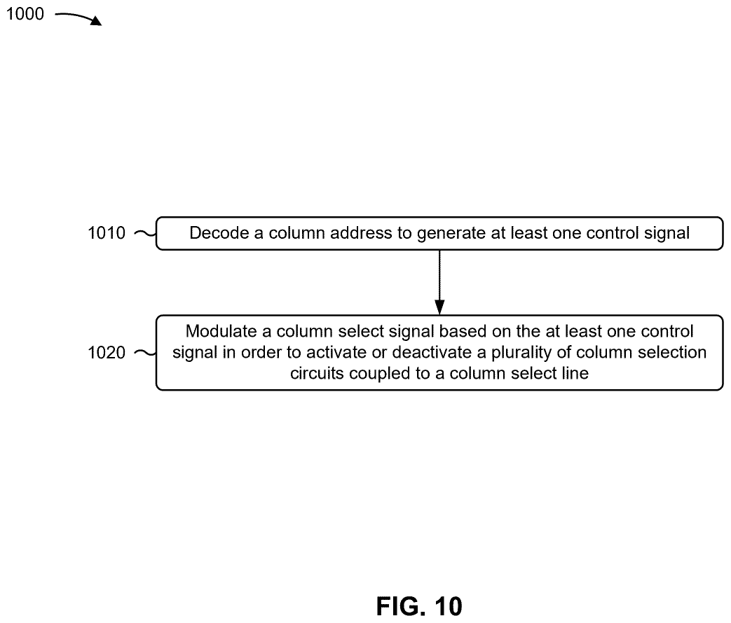

FIG. 10 is a flowchart of an example method 1000 associated with a low-voltage column select driver for a memory device. For example, the method 1000 may be a method for connecting and disconnecting a data I/O line and a bit line of the memory device. In some implementations, a column decoder (e.g., the column decoder 112) may perform or may be configured to perform the method 1000. Additionally, or alternatively, one or more components of the column decoder (e.g., CS driver 300, CS driver 701, CS driver 800, or CS driver 901) may perform or may be configured to perform one or more operations of method 1000. Thus, means for performing the method 1000 may include the column decoder and/or one or more components of the column decoder. Additionally, or alternatively, a non-transitory computer-readable medium may store one or more instructions that, when executed by the column decoder, cause the column decoder to perform the method 1000.

As shown in FIG. 10, the method 1000 may include decoding a column address to generate at least one control signal (block 1010). As further shown in FIG. 10, the method 1000 may include modulating a column select signal based on the at least one control signal in order to activate or deactivate a plurality of column selection circuits coupled to a column select line (block 1020). The plurality of column selection circuits may be configured to connect or disconnect the data I/O line and the bit line based on the at least one control signal. Modulating the column select signal may include generating an activation pulse for activating the plurality of column selection circuits during an activation interval, wherein the activation pulse comprises a first portion having a positive boost signal level and a second portion having an activation signal level that is less than the positive boost signal level, and wherein generating the activation pulse includes generating the first portion of the activation pulse for a first duration of the activation interval, and generating the second portion of the activation pulse for a second duration of the activation interval, the second duration of the activation interval being subsequent to the first duration of the activation interval.

The method 1000 may include additional aspects, such as any single aspect or any combination of aspects described in connection with one or more methods or operations described herein.

Although FIG. 10 shows example blocks of a method 1000, in some implementations, the method 1000 may include additional blocks, fewer blocks, different blocks, or differently arranged blocks than those depicted in FIG. 10. Additionally, or alternatively, two or more of the blocks of the method 1000 may be performed in parallel. The method 1000 is an example of one method that may be performed by one or more devices described herein. These one or more devices may perform or may be configured to perform one or more other methods based on operations described herein.

In some implementations, a memory device includes a bank comprising a memory array that includes a data line and a plurality of memory cells coupled to the data line; a data input/output (I/O) line for transmitting read data from the data line or write data to the data line; a column select line configured to carry a column select signal across a full height of the bank; a plurality of column selection circuits coupled to the column select line, wherein the plurality of column selection circuits are arranged along a length of the column select line, and wherein the plurality of column selection circuits are configured to connect or disconnect the data I/O line and the data line according to the column select signal; and a column decoder configured to decode a column address, wherein the column decoder comprises a column select driver configured to modulate the column select signal based on the column address in order to activate or deactivate the plurality of column selection circuits, wherein the column select signal comprises an activation pulse for activating the plurality of column selection circuits during an activation interval, wherein the activation pulse comprises a first portion having a positive boost signal level and a second portion having an activation signal level that is less than the positive boost signal level, and wherein the column select driver is configured to generate the first portion of the activation pulse for a first duration of the activation interval, and generate the second portion of the activation pulse for a second duration of the activation interval, the second duration of the activation interval being subsequent to the first duration of the activation interval.

In some implementations, a memory device includes a column decoder configured to decode a column address, wherein the column decoder comprises a column select driver configured to modulate a column select signal based on the column address in order to activate or deactivate a plurality of column selection circuits coupled to a column select line, wherein the column select signal comprises an activation pulse for activating the plurality of column selection circuits during an activation interval, wherein the activation pulse comprises a first portion having a positive boost signal level and a second portion having an activation signal level that is less than the positive boost signal level, and wherein the column select driver is configured to generate the first portion of the activation pulse for a first duration of the activation interval, and generate the second portion of the activation pulse for a second duration of the activation interval, the second duration of the activation interval being subsequent to the first duration of the activation interval.

In some implementations, a method of connecting and disconnecting a data input/output (I/O) line and a bit line of a memory device includes decoding a column address to generate at least one control signal; and modulating a column select signal based on the at least one control signal in order to activate or deactivate a plurality of column selection circuits coupled to a column select line, wherein the plurality of column selection circuits are configured to connect or disconnect the data I/O line and the bit line based on the at least one control signal, wherein modulating the column select signal includes: generating an activation pulse for activating the plurality of column selection circuits during an activation interval, wherein the activation pulse comprises a first portion having a positive boost signal level and a second portion having an activation signal level that is less than the positive boost signal level, and wherein generating the activation pulse includes generating the first portion of the activation pulse for a first duration of the activation interval, and generating the second portion of the activation pulse for a second duration of the activation interval, the second duration of the activation interval being subsequent to the first duration of the activation interval.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
a bank comprising a memory array that includes a data line and a plurality of memory cells coupled to the data line;
a data input/output (I/O) line for transmitting read data from the data line or write data to the data line;
a column select line configured to carry a column select signal across a full height of the bank;
a plurality of column selection circuits coupled to the column select line, wherein the plurality of column selection circuits are arranged along a length of the column select line, and wherein the plurality of column selection circuits are configured to connect or disconnect the data I/O line and the data line according to the column select signal; and
a column decoder configured to decode a column address, wherein the column decoder comprises a column select driver configured to modulate the column select signal based on the column address in order to activate or deactivate the plurality of column selection circuits,
wherein the column select signal comprises an activation pulse for activating the plurality of column selection circuits during an activation interval,
wherein the activation pulse comprises a first portion having a positive boost signal level and a second portion having an activation signal level that is less than the positive boost signal level, and
wherein the column select driver is configured to generate the first portion of the activation pulse for a first duration of the activation interval, and generate the second portion of the activation pulse for a second duration of the activation interval, the second duration of the activation interval being subsequent to the first duration of the activation interval.

2. The memory device of claim 1, wherein the plurality of column selection circuits are transistors, and
wherein the activation signal level is equal to or greater than a threshold voltage of each transistor.

3. The memory device of claim 1, wherein the column select driver includes a first inverter and a second inverter coupled in series,
wherein the first inverter is configured to receive a control signal corresponding to the column address,
wherein the second inverter has a first power supply terminal and a second power supply terminal, and
wherein the second inverter is coupled to an output of the first inverter and is configured to generate the column select signal corresponding to the control signal based on a first supply potential coupled to the first power supply terminal and a second supply potential coupled to the second power supply terminal.

4. The memory device of claim 3, wherein the first inverter comprises a first pair of high-voltage transistors, and wherein the second inverter comprises a second pair of high-voltage transistors.

5. The memory device of claim 3, wherein the column decoder is configured to toggle the control signal between the positive boost signal level and a ground potential based on the column address.

6. The memory device of claim 3, wherein the first inverter comprises a high-voltage positive-metal-oxide semiconductor (PMOS) transistor and a low-voltage negative-MOS (NMOS) transistor, and wherein the second inverter comprises a pair of low-voltage transistors.

7. The memory device of claim 6, wherein the column decoder is configured to toggle the control signal between the activation signal level and a ground potential based on the column address.

8. The memory device of claim 6, wherein a control electrode of the high-voltage PMOS transistor is coupled to an output of the second inverter.

9. The memory device of claim 3, wherein the column decoder comprises:
a first switch coupled between a first voltage source corresponding to the positive boost signal level and the first power supply terminal; and
a second switch coupled between a second voltage source corresponding to the activation signal level and the first power supply terminal,
wherein the column decoder is configured to control the first switch and the second switch based on the column address to generate the activation pulse.

10. The memory device of claim 1, wherein the column select driver is configured to deactivate the plurality of column selection circuits during a deactivation interval,
wherein the column select signal comprises a deactivation pulse for deactivating the plurality of column selection circuits during the deactivation interval, and
wherein the column select driver is configured to generate the deactivation pulse at a negative boost signal level for a first duration of the deactivation interval and maintain the column select signal at a deactivation signal level that is greater than the negative boost signal level for a second duration of the deactivation interval, the second duration of the deactivation interval being subsequent to the first duration of the deactivation interval.

11. The memory device of claim 10, wherein the deactivation signal level is less than a threshold voltage of each column selection circuit.

12. The memory device of claim 10, wherein the column select driver includes a first inverter and a second inverter coupled in series,
wherein the first inverter is configured to receive a control signal corresponding to the column address,
wherein the second inverter has a first power supply terminal and a second power supply terminal,
wherein the second inverter is coupled to an output of the first inverter and is configured to generate the column select signal corresponding to the control signal based on a first supply potential coupled to the first power supply terminal and a second supply potential coupled to the second power supply terminal, and
wherein the column decoder comprises:
a first switch coupled between a first voltage source corresponding to the positive boost signal level and the first power supply terminal;
a second switch coupled between a second voltage source corresponding to the activation signal level and the first power supply terminal;
a third switch coupled between a third voltage source corresponding to the negative boost signal level and the second power supply terminal; and
a fourth switch coupled between a fourth voltage source corresponding to the deactivation signal level and the second power supply terminal, and
wherein the column decoder is configured to control the first switch, the second switch, the third switch, and the fourth switch based on the column address to generate the column select signal with the activation pulse and the deactivation pulse.

13. The memory device of claim 10, wherein the first duration of the activation interval and the first duration of the deactivation interval are variable, and
wherein the column select driver is configured to receive a section control signal and regulate the first duration of the activation interval and the first duration of the deactivation interval based on the section control signal.

14. The memory device of claim 13, wherein the section control signal is a row address.

15. The memory device of claim 13, wherein the section control signal is a portion of the column address.

16. The memory device of claim 10, wherein a first difference between the positive boost signal level and the activation signal level is variable,
wherein a second difference between the negative boost signal level and the deactivation signal level is variable, and
wherein the column select driver is configured to receive a section control signal and regulate the first difference and the second difference based on the section control signal.

17. The memory device of claim 1, further comprising:
a column select ground line having a ground potential; and
a pull-down transistor coupled to the column select ground line and a far end of the column select line,
wherein the column select driver is configured to deactivate the plurality of column selection circuits during a deactivation interval,
wherein the column select driver is configured to maintain the column select signal at a deactivation signal level for the deactivation interval, and
wherein the column select driver is configured to turn on the pull-down transistor for a first duration of the deactivation interval to sink the column select signal to the column select ground line, and turn off the pull-down transistor for a second duration of the deactivation interval, the second duration of the deactivation interval being subsequent to the first duration of the deactivation interval.

18. The memory device of claim 1, wherein the column decoder is configured to generate a plurality of control signals based on the column address, and provide the plurality of control signals to the column select driver for generating the column select signal.

19. A memory device, comprising:
a column decoder configured to decode a column address, wherein the column decoder comprises a column select driver configured to modulate a column select signal based on the column address in order to activate or deactivate a plurality of column selection circuits coupled to a column select line,
wherein the column select signal comprises an activation pulse for activating the plurality of column selection circuits during an activation interval,
wherein the activation pulse comprises a first portion having a positive boost signal level and a second portion having an activation signal level that is less than the positive boost signal level, and
wherein the column select driver is configured to generate the first portion of the activation pulse for a first duration of the activation interval, and generate the second portion of the activation pulse for a second duration of the activation interval, the second duration of the activation interval being subsequent to the first duration of the activation interval.

20. A method of connecting and disconnecting a data input/output (I/O) line and a bit line of a memory device, the method comprising:
decoding a column address to generate at least one control signal; and
modulating a column select signal based on the at least one control signal in order to activate or deactivate a plurality of column selection circuits coupled to a column select line, wherein the plurality of column selection circuits are configured to connect or disconnect the data I/O line and the bit line based on the at least one control signal,
wherein modulating the column select signal includes:
generating an activation pulse for activating the plurality of column selection circuits during an activation interval, wherein the activation pulse comprises a first portion having a positive boost signal level and a second portion having an activation signal level that is less than the positive boost signal level, and
wherein generating the activation pulse includes:
generating the first portion of the activation pulse for a first duration of the activation interval, and generating the second portion of the activation pulse for a second duration of the activation interval, the second duration of the activation interval being subsequent to the first duration of the activation interval.
